(19) United States
(12) Patent Application Publication
(10) Pub. No.: US 2006/0228890 A1
(43) Pub. Date: Oct. 12, 2006

(54) Cleaning solution and method of forming a metal pattern for a semiconductor device using the same

(76) Inventors: Hyo-san Lee, Suwon-si (KR); Sang-yong Kim, Yongin-si (KR); Chang-ki Hong, Seongnam-si (KR); Sang-jun Choi, Seoul (KR); Woo-gwan Shim, Yongin-si (KR); Im-soo Park, Seoul (KR); Kui-jong Baik, Daejeon (KR); Woong Han, Gongju-si (KR); Jung-hun Lim, Daejeon (KR); Sang-won Lee, Gongju-si (KR); Sung-bae Kim, Seoul (KR); Hyun-tak Kim, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/402,028

(22) Filed: Apr. 12, 2006

(30) Foreign Application Priority Data
Apr. 12, 2005 (KR) 2005-0030429

(51) Int. Cl. C03C 15/00; H01L 21/302; B08B 6/00; C09K 13/00

(52) U.S. Cl. 438/689; 216/57; 252/79.1; 134/1.3

(57) ABSTRACT

A cleaning solution includes acetic acid, an inorganic acid, a fluoride compound, and deionized water, and may further include a corrosion inhibitor, a chelating agent, or a combination thereof. The cleaning solution may be used in the formation of a metal pattern in which a metal film including ruthenium is formed on a surface of a substrate, and a portion of the metal film is dry-etched to form a metal film pattern. After dry-etching, the metal film pattern is cleaned with the cleaning solution to remove an etching by-product layer around the metal film pattern. The cleaning solution may also be used to remove an etching by-product layer around an oxide film pattern prior to dry-etching of the metal film.

### BACKGROUND OF THE INVENTION

1. Field of the Invention

The present invention generally relates to the manufacture of semiconductor devices, and more particularly, the present invention relates to cleaning solutions used to remove polymer by-products produced during etching of oxide and/or metal films.

A claim of priority is made to Korean Patent Application No. 10-2005-0030429, filed on Apr. 12, 2005, in the Korean Intellectual Property Office, the disclosure of which is incorporated herein in its entirety by reference.

2. Description of the Related Art

As semiconductor memory devices become increasingly integrated, the unit area of memory cells of the devices is decreased. In memory devices employing capacitive elements, such as dynamic random access memories (DRAM's), the consequent decrease in cell capacitance is a significant hindrance to further increases in the integration degree.

In an effort to increase the cell capacitance in highly integrated semiconductor devices, a next generation capacitor structure has been proposed in which the upper and lower electrodes are made of ruthenium (Ru) instead of the more conventional doped polysilicon or titanium nitrite (TiN) electrodes. TiN has a work function of 4.5 eV, while Ru has a work function of 4.8 eV, and thus, Ru can produce a greater barrier height between a metal and an insulator. Accordingly, the use of Ru electrodes reduces leakage current.

However, when Ru is used in a metallization process, the possibility of metal contamination on a wafer is increased. That is, in a cleaning process, it is difficult to remove hard polymers, which are etching by-products, produced in large quantity after dry-etching of Ru wirings.

An organic cleaning solution including an amine group, for example, EKC 245 available from EKC Technologies Corporation, is typically used to remove polymer by-products produced after dry-etching of conventional metal wirings. However, polymer by-products produced after dry-etching of Ru wirings cannot be completely removed by the conventional cleaning solutions containing amine groups. Accordingly, it is generally necessary to execute a physical removal method, such as the use of Argon aerosol. The physical shock resulting from such physical removal methods can damage a wafer lower film. In addition, physical removal methods tend to be complicated to execute and exhibit relatively low reliability.

### SUMMARY OF THE INVENTION

According to an aspect of the present invention, a cleaning solution is provided which includes a mixed solution including acetic acid, an inorganic acid, a fluoride compound, and deionized water (DIW).

According to another aspect of the present invention, a method of forming a metal pattern is provided which includes forming a metal film including ruthenium on a surface of a substrate, forming a metal film pattern by dry-etching a portion of the metal film, and removing an etching by-product layer around the metal film pattern by cleaning the metal film pattern with a mixed solution comprising acetic acid, an inorganic acid, a fluoride compound, and deionized water (DIW).

### BRIEF DESCRIPTION OF THE DRAWINGS

The above and other features and advantages of the present invention will become readily apparent from the detailed description that follows, with reference to the accompanying drawings, in which:

FIGS. 1A through 1D are cross-sectional schematic views for use in explaining a method of forming a metal pattern according to a first embodiment of the present invention;

FIGS. 2A through 2C are cross-sectional schematic views for use in explaining a method of forming a metal pattern according to a second embodiment of the present invention;

FIGS. 3A and 3B are cross-sectional schematic views of samples used to evaluate the effectiveness of cleaning processes under various cleaning conditions;

FIGS. 4A and 4B are scanning electron microscope (SEM) images showing top and sectional surfaces of a product obtained after cleaning with a conventional cleaning solution after using an oxide film pattern as an etching mask;

FIGS. 4C and 4D are SEM images showing top and sectional surfaces of a product obtained after cleaning with a conventional cleaning solution after using a photoresist pattern as an etching mask;

FIG. 5A is a graph showing composition analysis results for the polymer residues in FIGS. 4B and 4B using auger electron spectroscopy (AES);

FIG. 5B is a graph showing composition analysis results for of the polymer residues in FIGS. 4C and 4D using AES;

FIG. 6 includes SEM images of products after cleaning the samples in FIGS. 3A and 3B using cleaning solutions having various compositions;

FIG. 7 includes SEM images of products after cleaning the samples in FIGS. 3A and 3B using the cleaning solutions of FIG. 6 with a fluoride compound additive;

FIG. 8 includes SEM images of products after cleaning the samples in FIGS. 3A and 3B using cleaning solutions having various compositions according to embodiments of the present invention;

FIG. 9 includes SEM images of products after removing polymer residues from the samples in FIGS. 3A and 3B using cleaning solutions according to embodiments of the present invention with various concentrations of a fluoride compound;

FIG. 10 includes SEM images of products after removing polymer residues from the samples in FIGS. 3A and 3B with cleaning solutions according to embodiments of the present invention with various concentrations of an inorganic acid;

FIG. 11 includes SEM images of products after removing polymer residues from the samples in FIGS. 3A and 3B with cleaning solutions according to embodiments of the present invention with various concentrations of acetic acid;

FIG. 12 includes SEM images of products after removing polymer residues from the samples in FIGS. 3A and 3B with cleaning solutions according to embodiments of the present invention at various temperatures;

FIG. 13A is a SEM image showing a sectional structure of a product after performing a cleaning process with a cleaning solution according to an embodiment of the present invention on an etched oxide film to be used as an etching mask;

FIG. 13B is a SEM image showing a top surface structure of a product after performing a cleaning process with a cleaning solution according to an embodiment of the present invention on an etched oxide film to be used as an etching mask; and

FIG. 14 includes SEM images showing sectional and top surfaces of products obtained after cleaning a substrate having an oxide film pattern with cleaning solutions according to embodiments of the present invention having a corrosion inhibitor and/or a chelating agent.

### DETAILED DESCRIPTION OF PREFERRED EMBODIMENTS

The present invention will now be described by way of preferred, but non-limiting, embodiments of the invention.

As an example, when a ruthenium (Ru) film, which can be employed to increase the capacitance of a capacitor in a semiconductor memory device, is dry-etched, residues such as hard polymers remain on the wafer after dry-etching of the Ru film. In order to effectively remove residues such as hard polymers formed after etching of the Ru film, a cleaning solution according to an embodiment of the present invention may be used which includes acetic acid as an organic acid, an inorganic acid, a fluoride compound, and deionized water (DIW) as basic components.

The concentration of the acetic acid may be about 30 to 90 wt %, preferably about 30 to 60 wt %, based on the total weight of the mixed solution according to the present invention. The concentration of the inorganic acid may be about 0.001 to 10 wt % based on the total weight of the mixed solution. The concentration of the fluoride compound may be about 0.001 to 5 wt % based on the total weight of the mixed solution. The DIW preferably makes up the remainder of the mixed solution, and preferably is included in a concentration of about 5 to 70 wt %. The cleaning solution according to the present embodiment may be maintained at a temperature of about 30 to 60° C.

The inorganic acid in the cleaning solution according to an embodiment of the present invention may be HNO₃, HCl, HClO₄, H₃PO₄, H₂SO₄H₅IO₆, or a combination of two or more thereof. Among these, the use of HNO₃ is preferable.

In addition, the fluoride compound in the cleaning solution according to an embodiment the present invention may be HF, NH₄F, or a combination thereof.

Typically, when a capacitor electrode of a semiconductor device is formed of Ru, a capping layer made of titanium nitride (TiN) is formed on an upper electrode. To prevent or reduce deterioration of the TiN film of the capping layer, the cleaning solution according to an embodiment of the present invention may further include a chelating agent, a corrosion inhibitor, or a mixture thereof.

The corrosion inhibitor may have an azole group compound. The concentration of the corrosion inhibitor may be about 0.001 to 5 wt % based on the total weight of the mixed solution. The corrosion inhibitor may include a triazole such as 1H-1,2,3-triazole or 1,2,4-triazole, a triazole derivative having a functional group, benzotriazole, imidazole, 1H-tetrazole, benzothiazole, oxazole, isoxazole, benzoxazole, pyrazole, or a combination of two or more thereof.

The concentration of the chelating agent may be about 0.001 to 10 wt % based on the total weight of the mixed solution. The chelating agent may include an amine such as monoethanol amine, diethanol amine, triethanol amine, diethylenetriamine, methylamine, ethylamine, propylamine (C₃H₇—NH₂), butylamine (C₄H₉—NH₂), or pentylamine (C₅H₁₁—NH₂). Otherwise, the chelating agent may include an amine carboxylic acid ligand such as diethylenetriamine pentaacetic acid. Alternatively, the chelating agent may include an amino acid such as glycine, alanine, valine, leucine, isoleucine, serine, threonine, tyrosine, phenylalanine, tryptophane, aspartic acid, glutamic acid, glutamine, asparagine, ricin, arginine, histidine, hydroxylysine, cysteine, methionine, cystine, proline, sulphamin acid, or hydroxyproline.

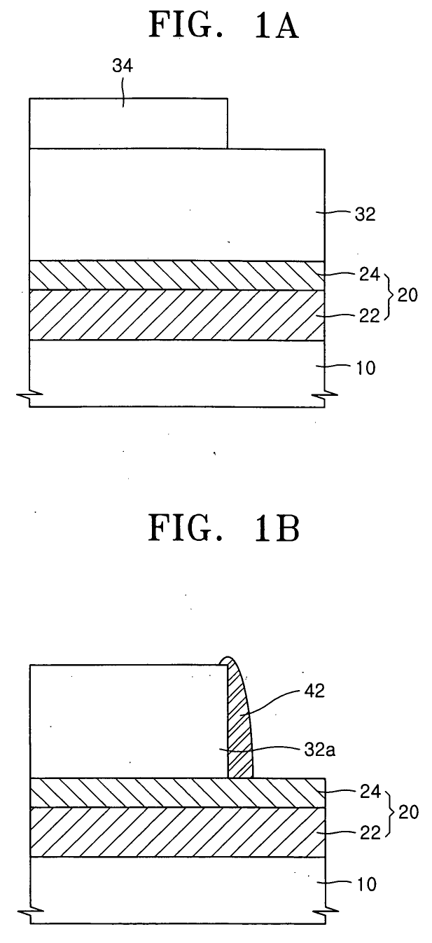

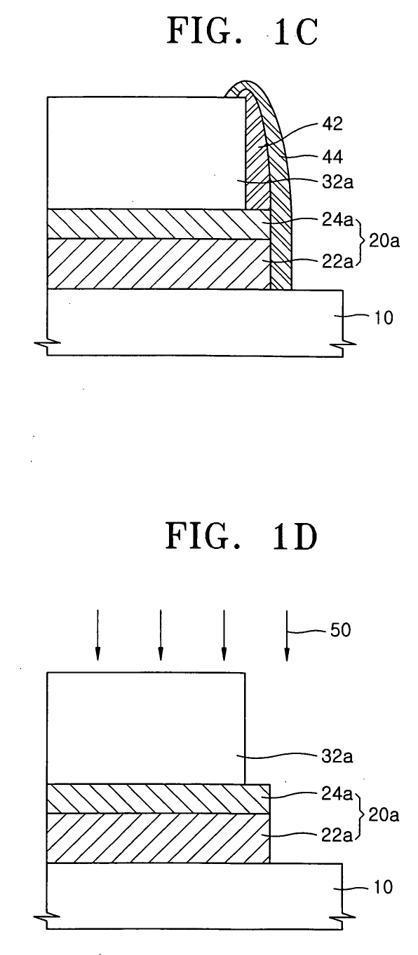

FIGS. 1A through 1D are cross-sectional schematic views for explaining a method of forming a metal pattern according to a first embodiment of the present invention.

Referring to FIG. 1A, a metal film 20 to be patterned is formed on a surface of a semiconductor substrate 10. In the example of FIG. 1, the metal film 20 is a two layer film including a first metal film 22 and a second metal film 24. The first metal film 22 may be a Ru film and the second metal film 24 may be a TiN film. However, the structure of the metal film 20, to which a method of forming a metal pattern according to an embodiment of the present invention can be applied, is not limited to the example of FIG. 1. That is, the metal film 20 may be formed as a single layer of a Ru film or a Ru alloy film. Alternatively, the metal film 20 may be formed as a multi-layer in which a Ru film or Ru alloy film and at least one metal-containing film are stacked.

Next, an oxide film 32 and a photoresist pattern 34, which will be used as an etching mask, are sequentially formed on the metal film 20.

Referring to FIG. 1B, the oxide film 32 is etched using the photoresist pattern 34 as an etching mask to form an oxide film pattern 32a, and then the photoresist pattern 34 is removed. As a result, polymer residues, a by-product of etching, are deposited around the oxide film pattern 32a, thereby forming a by-product layer 42. The by-product layer 42 is primarily formed on sidewalls of the oxide film pattern 32a.

Referring to FIG. 1C, the metal film is dry-etched using the oxide film pattern 32a as an etching mask to form a metal film pattern 20a including a first metal film pattern 22a and a second metal film pattern 24a. Here, if the first metal film pattern 22a is made of Ru, a mixed gas, for example, a mixed gas of C₄F₆, O₂, N₂ and Ar, may be used as an etching gas. The by-product layer 42 around the oxide film pattern 32a remains when etching the metal film 20 and thus functions as an etching mask. After dry-etching the metal film 20, a by-product layer 44 primarily made of hard polymers is formed around the metal film pattern 20a and the oxide film pattern 32a. As illustrated in FIG. 1C, the by-product layer 44 is primarily formed on the sidewall and a portion of a top surface of the oxide film pattern 32a.

Referring to FIG. 1D, the semiconductor substrate 10 on which the metal film pattern 20a is formed is cleaned with the above-described cleaning solution 50 (which includes acetic acid, an inorganic acid, a fluoride compound and DIW as components) to remove the by-product layers 42 and 44. The cleaning method may be a dipping method or a spray method. The cleaning solution 50 may include acetic acid, HNO₃, HF or NH₄F, and DIW. Preferably, the cleaning solution 50 includes acetic acid, HNO₃, NH₄F, and DIW. For example, the cleaning solution 50 may include about 40 wt % of acetic acid, about 1 wt % of HNO₃, and about 0.1 wt % of NH₄F with the remainder of the cleaning solution 50 being DIW. To remove the by-product layers 42 and 44, the temperature of the cleaning solution 50 may be maintained at about 30 to 60° C. It may be preferable to maintain the temperature of the cleaning solution 50 at about 60° C. when cleaning the semiconductor substrate 10 on which the metal film pattern 20a is formed.

The cleaning solution 50 may further include a corrosion inhibitor having an azole group compound. In addition, the cleaning solution 50 may further include a chelating agent including an amine, an amine carboxylic acid ligand or an amino acid.

As a result of the cleaning process using the cleaning solution 50 according to the present embodiment, the by-product layers 42 and 44 on the semiconductor substrate 10 are effectively removed.

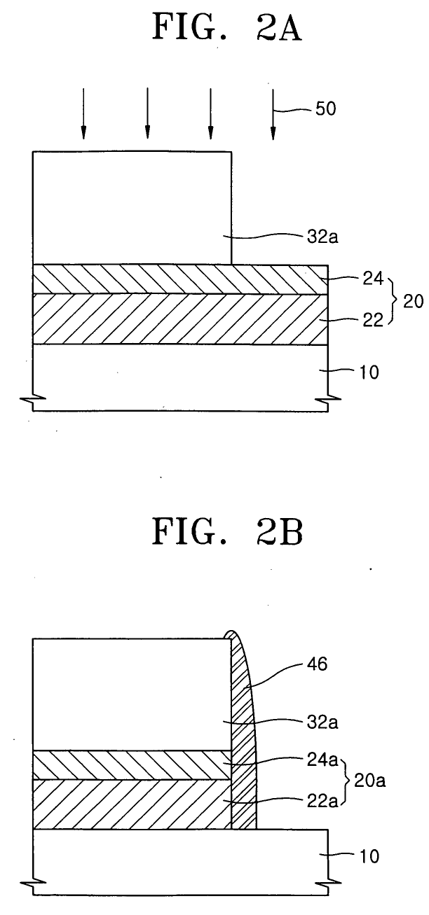

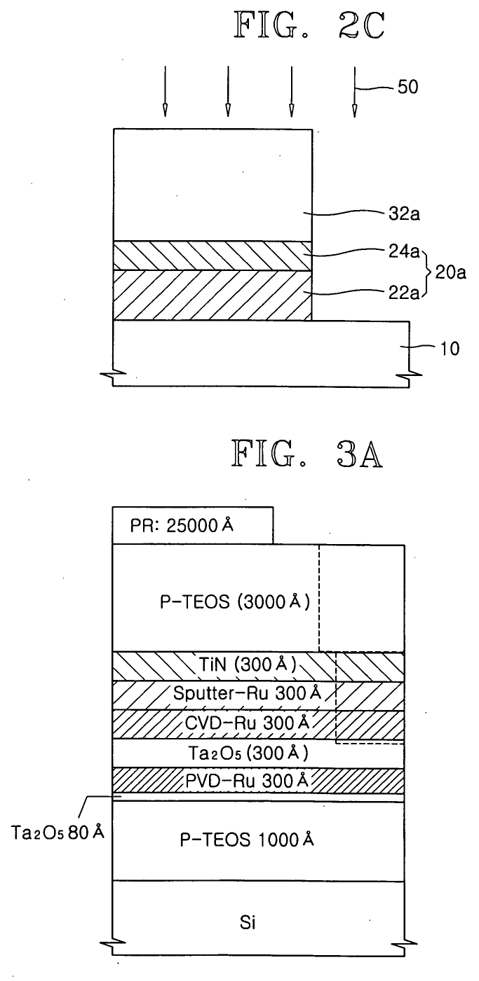

FIGS. 2A through 2C are cross-sectional views illustrating a method of forming a metal pattern according to a second embodiment of the present invention.

The second embodiment is similar to the first embodiment, with the addition of a process of removing a by-product layer 42 around an oxide film pattern 32a after formation of the oxide film pattern 32a and prior to etching of the metal film 20. In FIGS. 1A through 1D and 2A through 2C, like reference numerals refer to like elements.

Referring to FIG. 2A, the oxide film pattern 32a is formed on a surface of a semiconductor substrate 10. Next, the by-product layer 42 (FIG. 1C) adjacent the oxide film pattern 32a is removed with a cleaning solution 50 of an embodiment of the present invention. As a result, the by-product layer 42 is completely removed and sidewalls of the oxide film pattern 32a are exposed.

Referring to FIG. 2B, the metal film 20 is dry-etched using the oxide film pattern 32a as an etching mask to form a metal film pattern 20a having a first metal film pattern 22a and a second metal film pattern 24a. As a result, a by-product layer 46 made mainly of hard polymers is formed adjacent the metal film pattern 20a and oxide film pattern 32a.

Referring to FIG. 2C, the by-product layer 46 is removed by cleaning the semiconductor substrate 10 on which the metal film pattern 20a is formed with the cleaning solution 50 of an embodiment of the present invention. As a result of the cleaning process using the cleaning solution 50, the by-product layer 46 is effectively removed from the semiconductor substrate 10.

In both methods described above in connection with FIGS. 1A through 1D and FIGS. 2A through 2C, an oxide film pattern is used as an etching mask for etching a metal film like an Ru film. However, other types of masks, such as photoresist patterns, may be utilized. When using an oxide film pattern as an etching mask, as described with reference to FIGS. 1B and 1C, the by-product layers 42 and 44 are formed on the sidewall and a portion of top surface of the metal film pattern 20a, while, when using a photoresist pattern as an etching mask, a by-product hard polymer layer tends to remain entirely on a top surface of a semiconductor substrate on which the metal film pattern 20a is formed. In this case, the by-product layer can be effectively removed with the cleaning solution 50, in accordance with the process described with reference to FIGS. 1D.

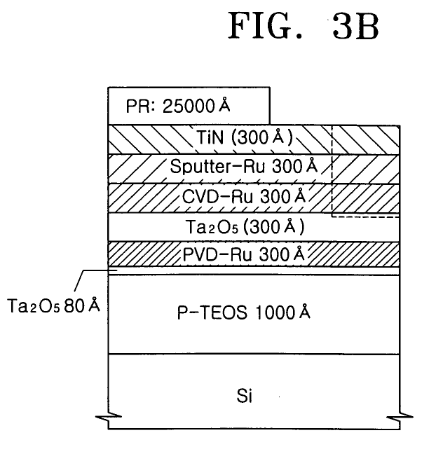

FIGS. 3A and 3B are cross-sectional views of samples used for evaluating the effectiveness of cleaning solutions under various cleaning conditions. As shown in FIGS. 3A and 3B, each of the samples includes a plasma-enhanced tetraethylorthosiliate film (P-TEOS film), a Ta₂O₅ film, an Ru film formed by physical vapor deposition (PVD) (indicated “PVD-Ru” in FIGS. 3A and 3B), a Ta₂O₅ film, an Ru film formed by chemical vapor deposition (CVD) (indicated “CVD-Ru” in FIGS. 3A and 3B), an Ru film formed by sputtering (indicated “Sputter-Ru” in FIGS. 3A and 3B), and a TiN film sequentially stacked on a silicon (Si) substrate.

For the sample illustrated in FIG. 3A, an oxide film pattern formed of P-TEOS is used as an etching mask, while for the sample illustrated in FIG. 3B, a photoresist pattern (PR) is used as an etching mask. Regions that will be etched using the etching masks are indicated with dotted lines in the stacked structures of FIGS. 3A and 3B.

### EXPERIMENTAL EXAMPLE 1

Each of the samples shown in FIGS. 3A and 3B was dry-etched to the Sputter-Ru film and the CVD-Ru film to form a plate electrode of a capacitor. A mixed gas of C₄F₆, O₂, N₂ and Ar was employed as an etching gas for etching the Ru film. Next, the etched products were cleaned with a commercially available EKC 245 stripper.

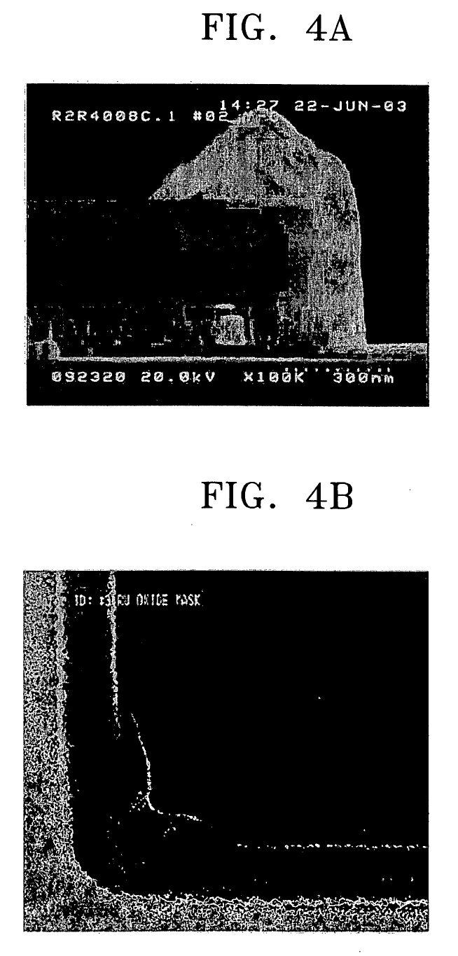

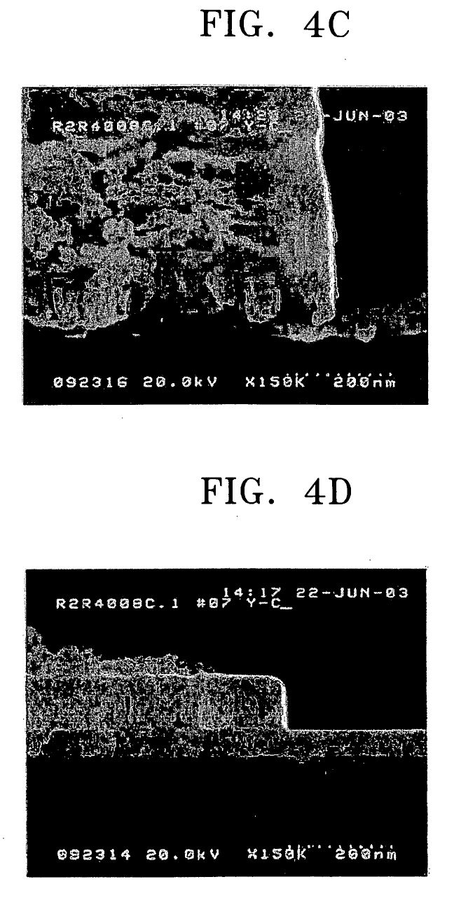

FIGS. 4B and 4B are scanning electron microscope (SEM) images showing top and sectional views of a product obtained after cleaning with EKC 245 subsequent to using an oxide film (P-TEOS) pattern as an etching mask as illustrated in FIG. 3A. FIGS. 4C and 4D are SEM images showing top and sectional views of a product obtained after cleaning with EKC 245 subsequent to using a photoresist pattern (PR) as an etching mask as illustrated in FIG. 3B.

As shown in the images of FIGS. 4A and 4B, when using an oxide film pattern as an etching mask, hard polymer residues remain on a sidewall and a portion of a top surface of a residual Ru film pattern (i.e. a plate electrode pattern). Referring to FIGS. 4C and 4D, when using a PR pattern as an etching mask, hard polymers remain mainly on a surface of a residual Ru film pattern (i.e. a plate electrode pattern). From these results, it can be seen that EKC 245 did not effectively remove etching-residues around an Ru film pattern produced after etching an Ru film.

### EXPERIMENTAL EXAMPLE 2

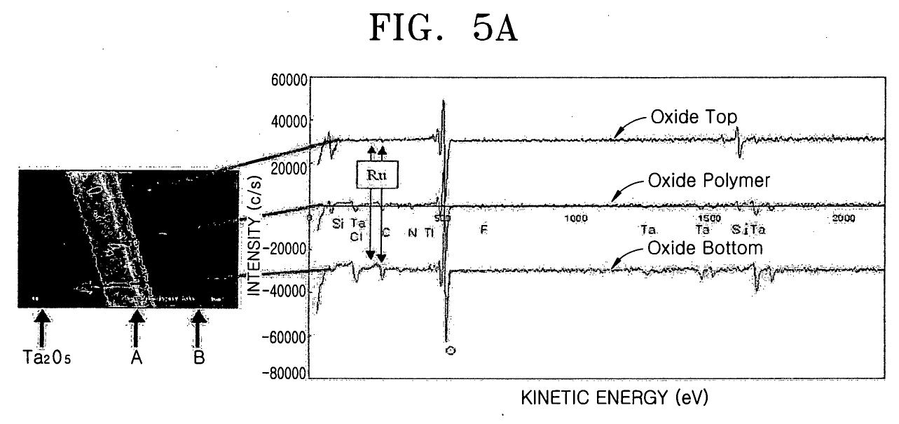

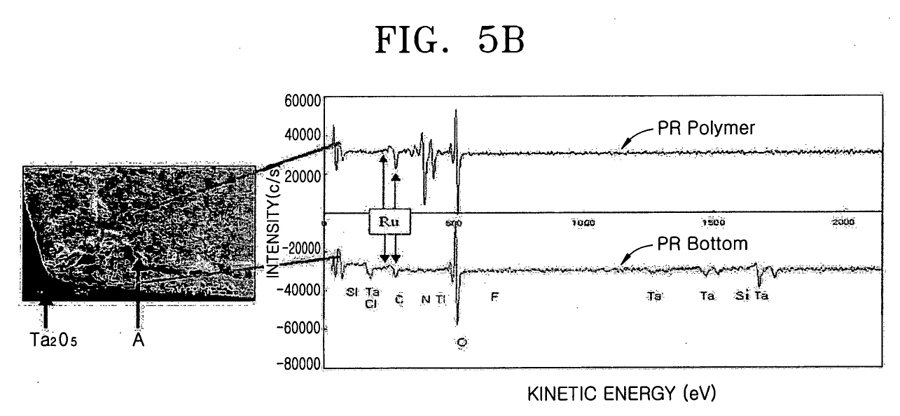

FIG. 5A illustrates composition analysis results for the polymer residues in FIGS. 4A and 4B using auger electron spectroscopy (AES), and FIG. 5B illustrates composition analysis results for the polymer residues in FIGS. 4C and 4D using AES.

In FIG. 5A, “A” indicates the polymer residues and “B” indicates the oxide film pattern. Referring to FIG. 5A, when using the oxide film pattern as an etching mask, the composition analysis results for the polymer residues using AES show that the major composition of the polymer residues is Ta₂O₅, which is the composition of the film under the etched Ru film. Although both Ru and C have very close peak positions in AES analysis graphs, which make it very difficult to identify them, the peaks in FIG. 5A may indicate the presence of Ru instead of C. Also, it is found that typical components, such as Ta, Ru, C, N, O and Cl, are present on the polymer layer (indicated “Oxide Polymer” in FIG. 5A). The presence of Ru, C, N, O, etc. is mainly found when using the PR pattern as an etching mask. From these results, it is determined that the etching-by-product polymer is composed of various metals and organic materials, as expected. Therefore, a process of removing these residues is required.

In order to remove the polymer residues composed of Ru, Ta, C, N, O, etc., the samples having structures of FIG. 3A or FIG. 3B were cleaned with cleaning solutions with various compositions, and then the cleaning effects of each of the cleaning solutions were evaluated. Specific experiments for those cases will be described below.

### EXPERIMENTAL EXAMPLE 3

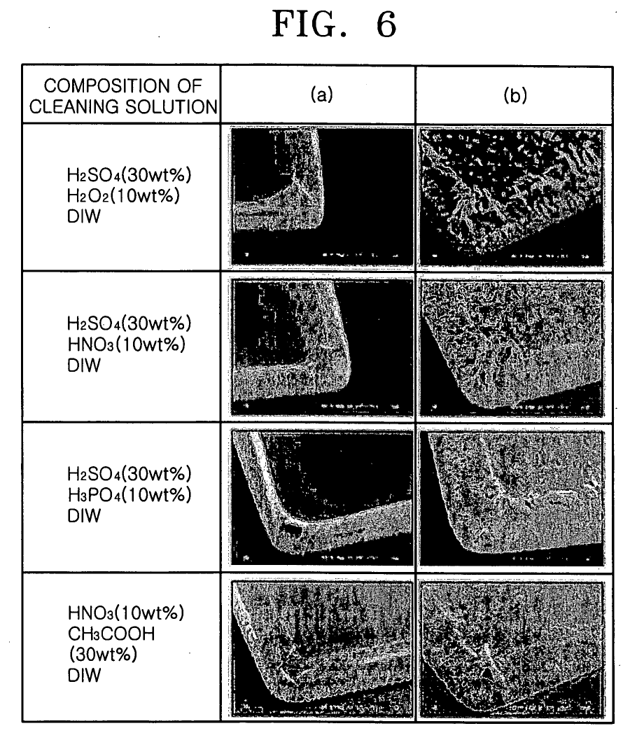

The samples of FIGS. 3A and 3B were cleaned with various inorganic cleaning solutions to evaluate their ability to clean the etching residues, and the results are shown in FIG. 6. Each cleaning solution used included two components selected from H₂O₂, HNO₃, H₂SO₄, H₃PO₄, and CH₃COOH (acetic acid). H₂O₂ a HNO₃ are oxidizing agents, H₂SO₄ can be used as an oxidizing agent and a solvent, H₃PO₄ can be used as a solvent because it forms a complex with a metal, and CH₃COOH is an organic material. The concentration of each component indicated in FIG. 6 is a weight percentage with respect to the total amount of the cleaning solution, and DIW is added to make up the remainder of the cleaning solutions. The temperature of each cleaning solution was maintained at 60° C. during cleaning. In FIG. 6, the results in column (a) were obtained when using an oxide film pattern as an etching mask, and the results in column (b) were obtained when using a PR pattern as an etching mask.

In FIG. 6, the use of a cleaning solution having HNO₃ and acetic acid for the case of an oxide film pattern etch mask shows favorable results, while in the remaining cases the polymer residues were barely removed.

### EXPERIMENTAL EXAMPLE 4

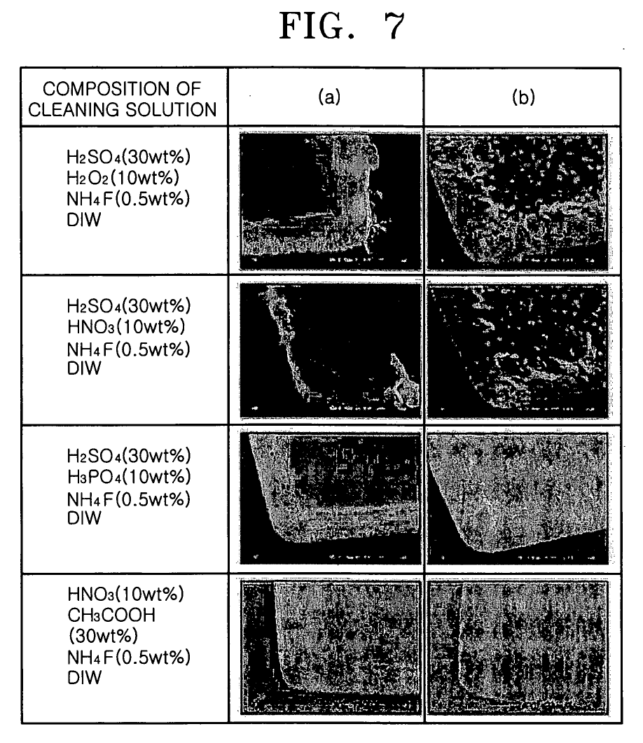

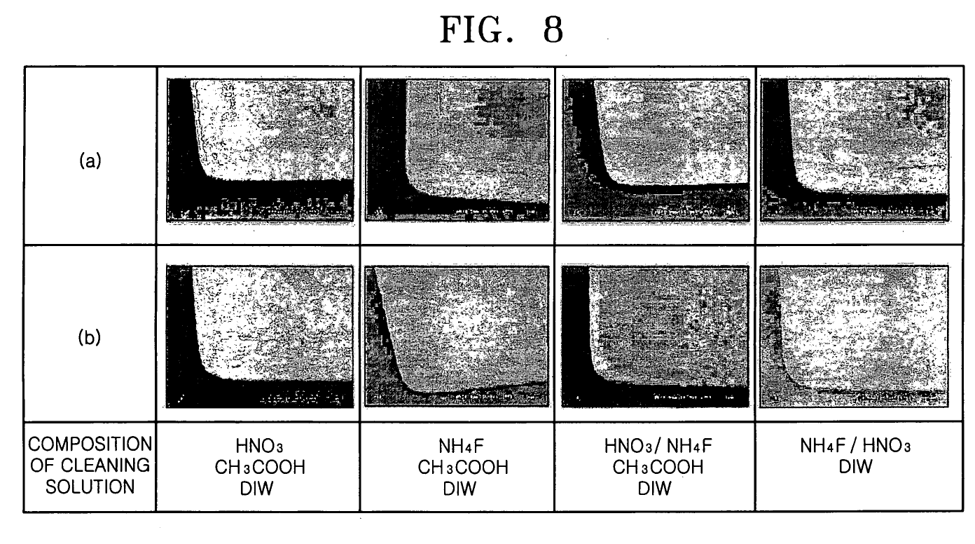

FIG. 7 shows the results of cleaning the samples of FIGS. 3A and 3B under the same conditions of FIG. 6, except that each of the cleaning solutions further included 0.5 wt % of a fluoride compound. As shown in FIG. 7, the addition of NH₄F as a fluoride compound greatly improves the removal of polymer residues, and particularly, the cleaning solution including HNO₃, CH₃COOH, and NH₄F performed best job of removing residues.

### EXPERIMENTAL EXAMPLE 5

Cleaning effects of cleaning solutions having various combinations of HNO₃, CH₃COOH, and NH₄F were evaluated. The temperature of each of the cleaning solutions was maintained at about 60° C. The results are shown in FIG. 8. Each of the cleaning solutions included a combination of 2 wt % of HNO₃, 0.2 wt % of NH₄F, and 30 wt % of CH₃COOH, and the remainder of the cleaning solution was DIW.

In FIG. 8, the results in row (a) were obtained when using an oxide film pattern as an etching mask, and the results in row (b) were obtained when using a PR pattern as an etching mask. The cleaning solution which included all of HNO₃, CH₃COOH, and NH₄F showed the most favorable results, as shown in FIG. 8.

To optimize a composition ratio for HNO₃, CH₃COOH, and NH₄F in a cleaning solution, the cleaning effects with respect to variations of the composition ratio were investigated.

### EXPERIMENTAL EXAMPLE 6

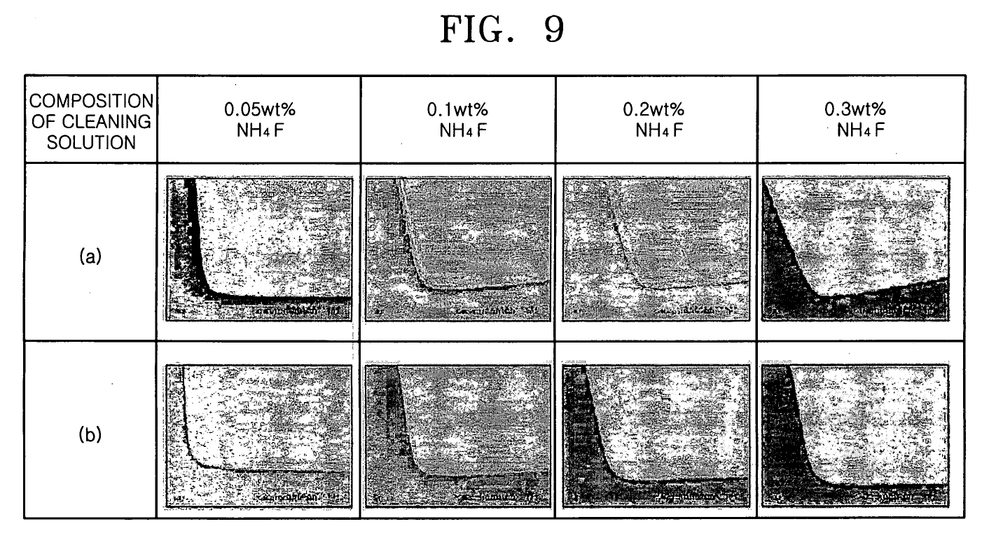

A cleaning solution including HNO₃, CH₃COOH, and NH₄F was used. The concentration of HNO₃ in the cleaning solution was fixed at 1 wt % and the concentration of CH₃COOH in the cleaning solution was fixed at 40 wt %. By setting the concentration of NH₄F in the cleaning solution to 0.05, 0.1, 0.2, and 0.3 wt %, features of removing the polymer residues with each of the cleaning solutions were investigated. The temperature of each of the cleaning solutions was maintained at about 60° C. during cleaning. The results are shown in FIG. 9. In FIG. 9, the results in row (a) were obtained when using an oxide film pattern as an etching mask, and the results in row (b) were obtained when using a PR pattern as an etching mask.

As shown in FIG. 9, polymer residues were almost completely removed when the concentration of NH₄F was more than 0.1 wt %. However, the oxide film pattern used as an etching mask is etched when the concentration of NH₄F was more than 0.2 wt %, and was completely removed when the concentration of NH₄F was 0.3 wt %. Therefore, the optimum concentration of NH₄F may be 0.1 wt %. In addition, a narrow band structure is shown along the edge of the top surface of the oxide film pattern in row (a), which is because polymers produced in an etching process for forming an oxide film pattern act as an etching mask during subsequent etching of a Ru film. This can be eliminated by performing a cleaning process with a cleaning solution according to an embodiment of the present invention after etching an oxide film to form an oxide film pattern.

### EXPERIMENTAL EXAMPLE 7

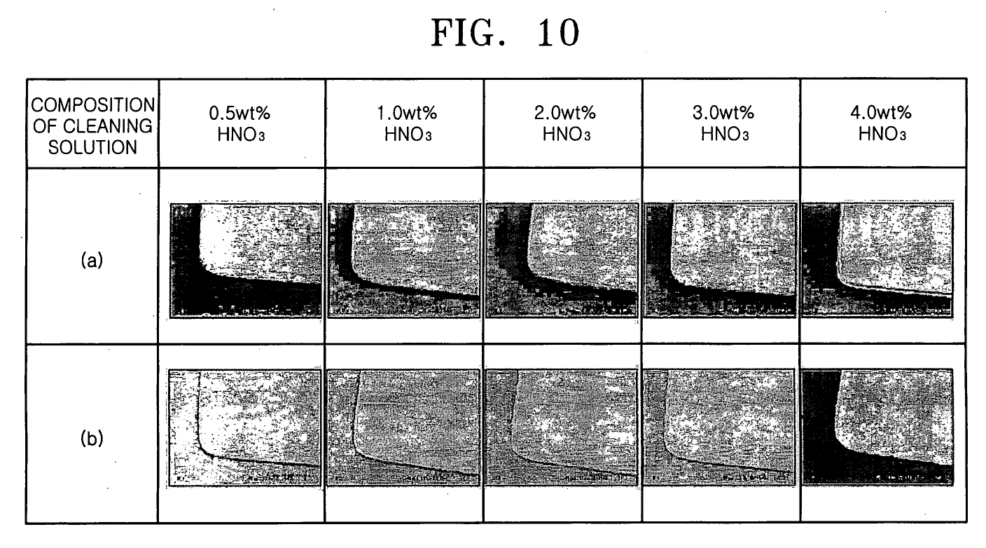

A cleaning solution including HNO₃, CH₃COOH, and NH₄F was used. The concentration of CH₃COOH in the cleaning solution was fixed at 40 wt % and the concentration of NH₄F in the cleaning solution was fixed at 0.1 wt %. By setting the concentration of HNO₃ in the cleaning solution to 0.5, 1.0, 2.0, 3.0, and 4.0 wt %, features of removing the polymer residues with each of the cleaning solutions were investigated. The temperature of each of the cleaning solutions was maintained at about 60° C. The results are shown in FIG. 10. In FIG. 10, the results in row (a) were obtained when using an oxide film pattern as an etching mask, and the results in row (b) were obtained when using a PR pattern as an etching mask.

The results of using a cleaning solution which included 1.0 wt % and 2.0 wt % of HNO₃ showed the most favorable results with respect to removing polymer residues, as shown in FIG. 10.

### EXPERIMENTAL EXAMPLE 8

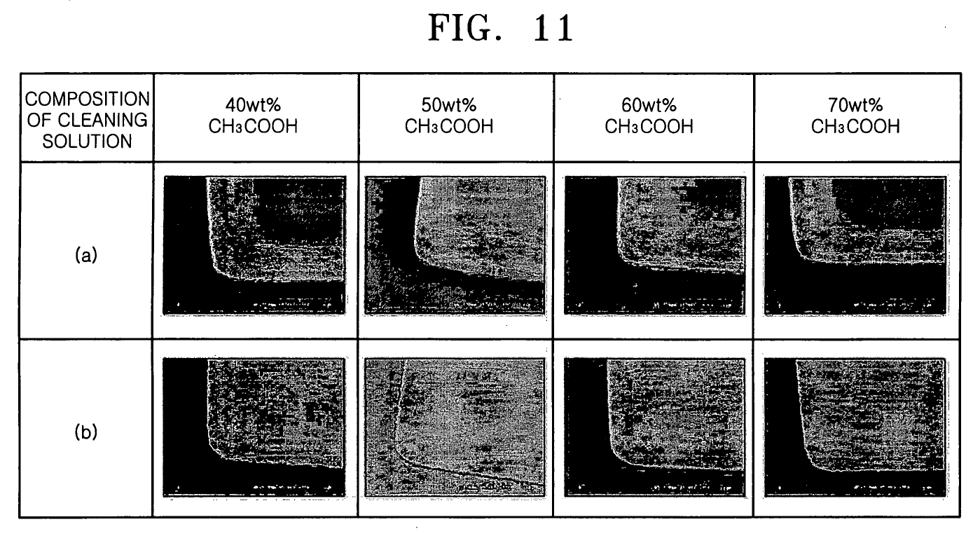

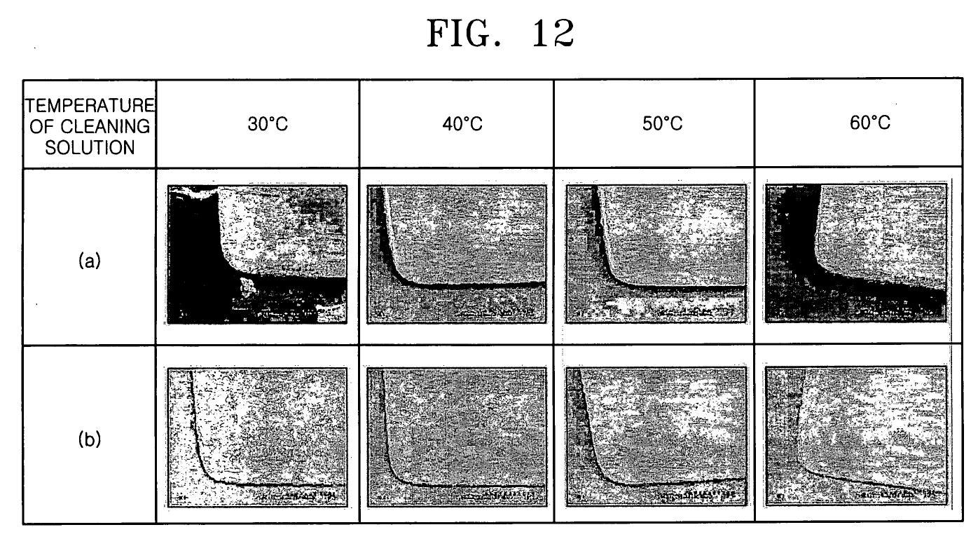

A cleaning solution including HNO₃, CH₃COOH, and NH₄F was used. The concentration of NH₄F in the cleaning solution was fixed at 0.1 wt % and the concentration of HNO₃ in the cleaning solution was fixed at 1 wt %. By setting the concentration of CH₃COOH in the cleaning solution to 40, 50, 60, and 70 wt %, features of removing the polymer residues with each of the cleaning solutions were investigated. The temperature of each of the cleaning solutions was maintained at about 60° C. during cleaning. The results are shown in FIG. 11. In FIG. 11, the results in row (a) were obtained when using an oxide film pattern as an etching mask, and the results in row (b) were obtained when using a PR pattern as an etching mask.

The results of using a cleaning solution which included 40 wt % and 50 wt % of CH₃COOH showed the most favorable results with respect to removing polymer residues, as shown in FIG. 11.

### EXPERIMENTAL EXAMPLE 9

FIG. 12 is SEM images of products after removing polymer residues at various temperatures using a cleaning solution according to an embodiment of the present invention. The cleaning solution having 0.1 wt % of NH₄F, 40 wt % of CH₃COOH and 1 wt % of HNO₃ was used. In FIG. 12, the results in row (a) were obtained when using an oxide film pattern as an etching mask, and the results in row (b) were obtained when using a PR pattern as an etching mask.

As shown in FIG. 12, a cleaning temperature at 60° C. showed the most favorable results with respect to removing polymer residues.

### EXPERIMENTAL EXAMPLE 10

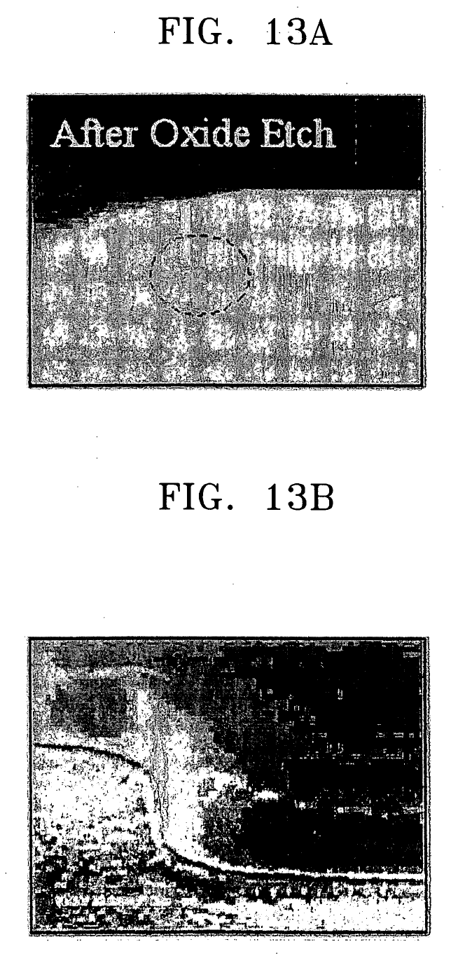

Based on the results of the experimental examples 1 through 9, a cleaning solution was optimized by using 0.1 wt % of NH₄F, 40 wt % of CH₃COOH, and 1 wt % of HNO₃ for the following experiments. A sample having the structure shown in FIG. 3A was prepared. An oxide film thereof was dry-etched to form an oxide film pattern to be used as an etching mask. A subsequent cleaning process with the cleaning solution was performed at about 60° C. to remove polymer by-products on a substrate. The results are shown in FIGS. 13A and 13B. FIG. 13A is a SEM image showing a sectional structure of a product obtained after performing a cleaning process on an etched oxide film. FIG. 13B is a SEM image showing a top surface of the same product in FIG. 13A.

As shown in the circular portion defined by the dotted line in FIG. 13A, a capping layer composed of a TiN film (TiN film in FIG. 3A), which is formed for supplementary adhesion between an oxide film pattern and a Ru film, is partially removed by the cleaning solution in the cleaning process, resulting in cleavage between the oxide film pattern and the Ru film.

### EXPERIMENTAL EXAMPLE 11

When using an oxide film pattern as an etching mask, in order to prevent damage to a capping layer, which is formed for supplementary adhesion between an oxide film pattern and a Ru film, when cleaning with a cleaning solution according to an embodiment of the present invention immediately after etching the oxide film, an additive is added to the cleaning solution used in experimental example 10.

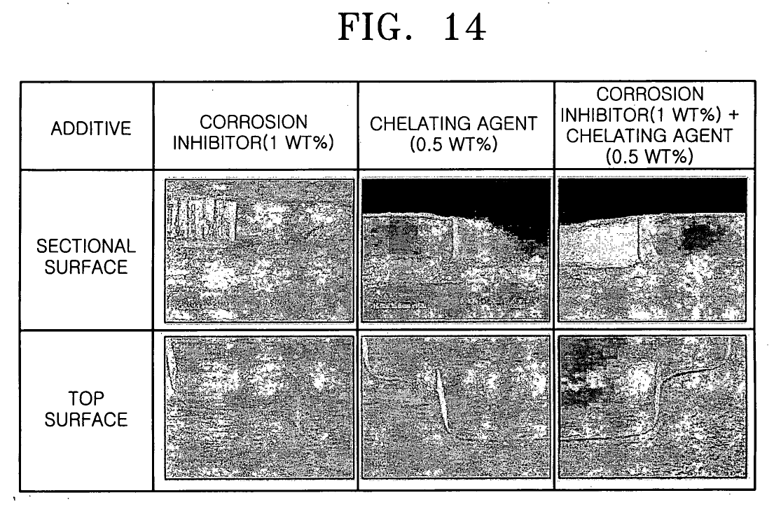

FIG. 14 shows the results of cleaning substrates on which oxide film patterns were performed with cleaning solutions having various additives. The additives were a corrosion inhibitor having an azole group compound which is known to protect TiN, and a chelating agent. FIG. 14 shows SEM images of the sectional and top surfaces of each of the products.

Referring to FIG. 14, the same cleaning solution as used in experimental example 10 was used, with an additive of 1 wt % of triazole as a corrosion inhibitor, with an additive of 0.5 wt % of ethylene diamine tetraacetic acid (EDTA) triazole as a chelating agent, and with an additive of both 1 wt % of triazole and 0.5 wt % of ethylene diamine tetraacetic acid (EDTA) triazole. The temperature of the cleaning solution was maintained at about 60° C. during cleaning.

From the results of FIG. 14, individually or synchronously adding the corrosion inhibitor and the chelating agent to the cleaning solution including HNO₃, CH₃COOH, and NH₄F as basic components prevented or reduced damage to the TiN capping layer.

Although not illustrated in the drawings, when etching the Ru film using the oxide film pattern as an etching mask, the additives do not affect the removal of the polymer residues.

A cleaning solution according to embodiments of the present invention is a mixed solution including acetic acid, an inorganic acid, a fluoride compound, and DIW. The cleaning solution may be effectively used to remove hard polymers of etching by-products produced by dry-etching a metal film, particularly, an Ru film, in a process of manufacturing a semiconductor device. Also, in the case of dry-etching an Ru film using an oxide film pattern as an etching mask, an etching profile of the metal film can be improved if a hard polymer by-product layer formed around an oxide film pattern is first cleaned with the cleaning solution before etching the Ru film. The cleaning solution may further include a corrosion inhibitor and/or a chelating agent to prevent or reduce damage to a TiN film used as a capping layer of an Ru film.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A cleaning solution comprising a mixed solution including acetic acid, an inorganic acid, a fluoride compound, and deionized water (DIW).

2. The cleaning solution of claim 1, wherein the concentration of the acetic acid in the mixed solution is 30 to 90 wt % based on a total weight of the mixed solution.

3. The cleaning solution of claim 1, wherein the concentration of the inorganic acid in the mixed solution is 0.001 to 10 wt % based on a total weight of the mixed solution.

4. The cleaning solution of claim 1, wherein the concentration of the fluoride compound in the mixed solution is 0.001 to 5% wt % based on a total weight of the mixed solution.

5. The cleaning solution of claim 1, wherein the concentration of the DIW in the mixed solution is 5 to 70 wt % based on a total weight of the mixed solution.

6. The cleaning solution of claim 1, wherein the inorganic acid is one selected from the group consisting of HNO₃, HCl, HClO₄, H₃PO₄, H₂SO₄, H₅IO₆, and combinations of any two or more thereof.

7. The cleaning solution of claim 1, wherein the fluoride compound is one of HF, NH₄F, and a combination thereof.

8. The cleaning solution of claim 1, wherein the mixed solution is maintained at a temperature of about 30 to 60° C.

9. The cleaning solution of claim 1, wherein the mixed solution further comprises a corrosion inhibitor.

10. The cleaning solution of claim 9, wherein the concentration of the corrosion inhibitor in the mixed solution is 0.001 to 5 wt % based on the total weight of the mixed solution.

11. The cleaning solution of claim 9, wherein the corrosion inhibitor comprises an azole group compound.

12. The cleaning solution of claim 1, wherein the mixed solution further comprises a chelating agent.

13. The cleaning solution of claim 12, wherein the concentration of the chelating agent in the mixed solution is 0.001 to 10 wt % based on the total weight of the mixed solution.

14. The cleaning solution of claim 12, wherein the chelating agent comprises at least one of an amine, an amine carboxylic acid ligand, and an amino acid.

15. A method of forming a metal pattern, said method comprising:
forming a metal film comprising ruthenium on a surface of a substrate;
forming a metal film pattern by dry-etching a portion of the metal film; and
removing an etching by-product layer around the metal film pattern by cleaning the metal film pattern with a mixed solution comprising acetic acid, an inorganic acid, a fluoride compound, and deionized water (DIW).

16. The method of claim 15, wherein the inorganic acid is one selected from the group consisting of HNO₃, HCl, HClO₄, H₃PO₄, H₂SO₄, H₅IO₆, and combinations of any two or more thereof.

17. The method of claim 15, wherein the fluoride compound is one of HF, NH₄F, and a combination thereof.

18. The method of claim 15, wherein the metal film pattern is cleaned at a temperature of about 30 to 60° C.

19. The method of claim 15, wherein the mixed solution further comprises a corrosion inhibitor having an azole group compound.

20. The method of claim 15, wherein the mixed solution further comprises a chelating agent including at least one of an amine, an amine carboxylic acid ligand and an amino acid.

21. The method of claim 15, wherein the cleaning operation is performed using a dipping method or a spraying method.

22. The method of claim 15, wherein the forming of the metal film pattern comprises:
forming an oxide film on the metal film;
forming an oxide film pattern by dry-etching a portion of the oxide film; and
dry-etching the metal film using the oxide film pattern as an etching mask.

23. The method of claim 22, wherein the etching by-product layer includes by-products resulting from the dry-etching of the oxide film and by-products resulting from the dry-etching of the metal film.

24. The method of claim 22, wherein the etching by-product layer is a second etching by-product layer and the mixed solution is a second mixed solution,
wherein said method further comprises, prior to dry-etching the metal film, removing a first etching by-product layer around the oxide film pattern with a first mixed solution comprising acetic acid, an inorganic acid, a fluoride compound and DIW, and
wherein the first etching by-product layer includes by-products resulting from the dry-etching of the oxide film and the second etching by-product layer includes by-products resulting from the dry-etching of the metal film.

25. The method of claim 24, wherein the inorganic acid of the first mixed solution is selected from the group consisting of HNO₃, HCl, HClO₄, H₃PO₄, H₂SO₄, H₅IO₆, and combinations of any two or more thereof.

26. The method of claim 25, wherein the fluoride compound is one of HF, NH₄F, and a combination thereof.

27. The method of claim 24, wherein the first etching by-product layer is removed at a temperature of about 30 to 60° C.

28. The method of claim 24, wherein the first mixed solution further comprises a corrosion inhibitor comprising an azole group compound.

29. The method of claim 24, wherein the first mixed solution further comprise a chelating agent including at least one of an amine, an amine carboxylic acid ligand and an amino acid.

30. The method of claim 24, wherein the first etching by-product layer is removed using a dipping method or a spraying method.
